(19) United States
(12) Patent Application Publication
(10) Pub. No.: US 2025/0040119 A1
(43) Pub. Date: Jan. 30, 2025

(54) METHOD FOR MANUFACTURING SEMICONDUCTOR APPARATUS INCLUDING REDISTRIBUTION LAYER STRUCTURE

(71) Applicant: MICRON TECHNOLOGY, INC., Boise, ID (US)

(72) Inventor: KEISUKE SHIMADA, Higashihiroshima (JP)

(73) Assignee: MICRON TECHNOLOGY, INC., Boise, ID (US)

(21) Appl. No.: 18/747,998

(22) Filed: Jun. 19, 2024

Related U.S. Application Data
(60) Provisional application No. 63/515,906, filed on Jul. 27, 2023.

(51) Int. Cl. H10B 12/00

(52) U.S. Cl. CPC H10B 12/09

(57) ABSTRACT

According to one or more embodiments of the disclosure, a method comprises forming a plurality of poly contact portions on a semiconductor substrate, forming a plurality of contact holes to the plurality of poly contact portions, forming a plurality of conductive portions to the plurality of contact holes.

### CROSS REFERENCE TO RELATED APPLICATION(S)

This application claims the benefit under 35 U.S.C. § 119 of the earlier filing date of U.S. Provisional Application Ser. No. 63/515,906, filed Jul. 27, 2023, the entire contents of which are hereby incorporated by reference in its entirety for any purpose.

### BACKGROUND

A semiconductor apparatus may include a semiconductor device, such as a memory device. A semiconductor device may include a layer stack structure on a semiconductor substrate. The layer stack structure may include a multi-layer wiring structure and a redistribution layer structure. A multi-layer wiring structure may include a plurality of metal layers stacked with one another. The stacked metal layers may be electrically connected or coupled to one another by one or more conductive contacts and vias. A redistribution layer structure may be provided on a top metal layer of the stacked metal layers of the multi-layer wiring structure. The redistribution layer structure may include a redistribution layer, an insulating layer, a contact, and such. The redistribution layer structure improves efficiency of a wiring layout and a circuit array layout.

A memory device may include memory regions and periphery regions. The memory regions include memory banks of memory cells that are accessed for data read and write. The periphery regions are provided adjacent to or around the memory regions and include various circuits for memory operations. The wiring layout and the circuit array layout of the memory and periphery regions may be improved by forming the redistribution layer structure at appropriate positions. The redistribution layer structure may be formed during wiring forming processing, such as a back end of line (BEOL).

### BRIEF DESCRIPTION OF THE DRAWINGS

FIG. 1 depicts an example of a block diagram of a memory device as a semiconductor device in a plan view according to an embodiment of the disclosure.

FIGS. 2Aa-2Ac depict an example of part of processes for forming at least part of a memory device including a memory region and a periphery region in a plan view and cross-sectional views according to an embodiment of the disclosure.

FIGS. 2Ba-2Bc depict an example of part of processes for forming at least part of a memory device including a memory region and a periphery region in a plan view and cross-sectional views according to an embodiment of the disclosure.

FIGS. 2Ca-2Cc depict an example of part of processes for forming at least part of a memory device including a memory region and a periphery region in a plan view and cross-sectional views according to an embodiment of the disclosure.

FIGS. 2Da-2Dc depict an example of processes of forming at least part of a memory device including a memory region and a periphery region in a plan view and cross-sectional views according to an embodiment of the disclosure.

FIGS. 2Ea-2Ec depict an example of part of processes for forming at least part of a memory device including a memory region and a periphery region in a plan view and cross-sectional views according to an embodiment of the disclosure.

FIGS. 2Fa-2Fc depict an example of part of processes for forming at least part of a memory device including a memory region and a periphery region in a plan view and cross-sectional views according to an embodiment of the disclosure.

FIGS. 2Ga-2Gc depict an example of part of processes for forming at least part of a memory device including a memory region and a periphery region in a plan view and cross-sectional views according to an embodiment of the disclosure.

FIGS. 2Ha-2Hc depict an example an example of part of processes for forming at least part of a memory device including a memory region and a periphery region in a plan view and cross-sectional views according to an embodiment of the disclosure.

FIGS. 2Ia-2Ic depict an example of part of processes for forming at least part of a memory device including a memory region and a periphery region in a plan view and cross-sectional views according to an embodiment of the disclosure.

FIGS. 2Ja-2Jc depict an example of part of processes for forming at least part of a memory device including a memory region and a periphery region in a plan view and cross-sectional views according to an embodiment of the disclosure.

FIGS. 2Ka-2Kc depict an example of part of processes for forming at least part of a memory device including a memory region and a periphery region in a plan view and cross-sectional views according to an embodiment of the disclosure.

FIGS. 2La-2Lc depict an example of part of processes for forming at least part of a memory device including a memory region and a periphery region in a plan view and cross-sectional views according to an embodiment of the disclosure.

FIGS. 2Ma-2Mc depict an example of part of processes for forming at least part of a memory device including a memory region and a periphery region in a plan view and cross-sectional views according to an embodiment of the disclosure.

FIGS. 2Na-2Nc depict an example of part of processes for forming at least part of a memory device including a memory region and a periphery region in a plan view and cross-sectional views according to an embodiment of the disclosure.

FIGS. 2Oa-2Oc depict an example of part of processes for forming at least part of a memory device including a memory region and a periphery region in a plan view and cross-sectional views according to an embodiment of the disclosure.

FIGS. 2Pa-2Pc depict an example of part of processes for forming at least part of a memory device including a memory region and a periphery region in a plan view and cross-sectional views according to an embodiment of the disclosure.

FIGS. 2Qa-2Qc depict an example of part of processes for forming at least part of a memory device including a memory region and a periphery region in a plan view and cross-sectional views according to an embodiment of the disclosure.

FIGS. 2Ra-2Rc depict an example of part of processes for forming at least part of a memory device including a memory region and a periphery region in a plan view and cross-sectional views according to an embodiment of the disclosure.

FIG. 3 depicts an example of a schematic configuration of a semiconductor system according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for case of illustration. In the drawings, the dimensions and dimensional ratios of each unit do not necessarily match the actual dimensions and dimensional ratios in the embodiments.

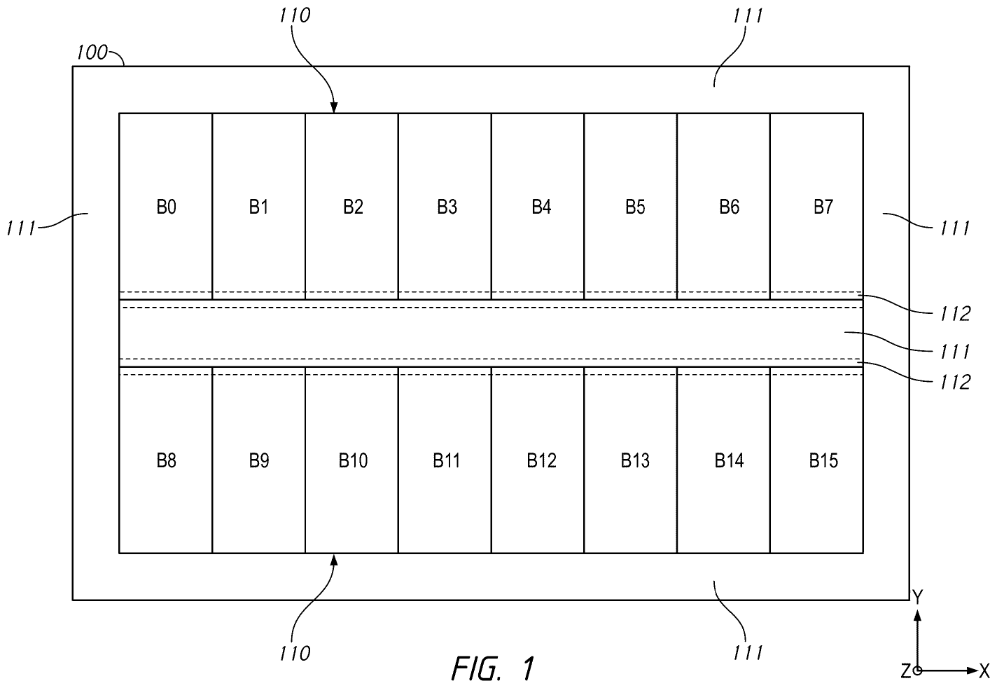

FIG. 1 depicts an example of a block diagram of a memory device 100 in a plan view according to an embodiment of the disclosure. The memory device 100 may be one example of a semiconductor device. The memory device 100 may be one example of a semiconductor apparatus. The memory device 100 includes one or more memory regions (may also be referred to as cell regions) 110 and one or more periphery regions (may also be referred as peripheral regions) 111. The memory regions 110 include a plurality of memory banks of memory cells. In the example, the memory device 100 includes a pair of the memory regions 110 arranged in two rows that are extending in one horizontal direction (for example, a direction along an X-axis in the drawing) and neighboring with each other in another horizontal direction (for example, a direction along a Y-axis perpendicular to the X-axis direction in the drawing). The memory regions 110 of the pair include, respectively, a first group of memory banks BANK0-BANK7 (B0-B7) and a second group of memory banks BANK8-BANK15 (B8-B15). The memory banks in each group are arranged next to each other in the corresponding row. The memory banks may be accessed to read data from and write data to the memory cells. In the example, one periphery region 111 is provided between the memory regions 110. The periphery region 111 is adjacent to the memory regions 110 with boundaries or boundary regions 112 therebetween. Regions around the memory regions 110 may also be the periphery regions 111 including boundaries or boundary regions with the neighboring memory regions 110. Various circuits and circuit elements (for example, transistors) that are used for memory operations are included in the periphery regions 111. Such circuits and circuit elements in the periphery regions 111 are electrically connected to or electrically coupled to the memory cells in the memory regions 110 via, for example, conductive wirings or wiring layers, and conductive contacts. The number, the position, the arrangement and such of the memory regions 110 as well as those of the memory banks and/or memory cells are not limited to the examples and the embodiments described herein. The number, the position, the arrangement and such of the periphery regions 111 are not limited to the examples and the embodiments described herein. The memory regions 110 and the periphery regions 111 are formed on a semiconductor substrate or a semiconductor wafer (not separately depicted) by multiple processes of a plurality of layers.

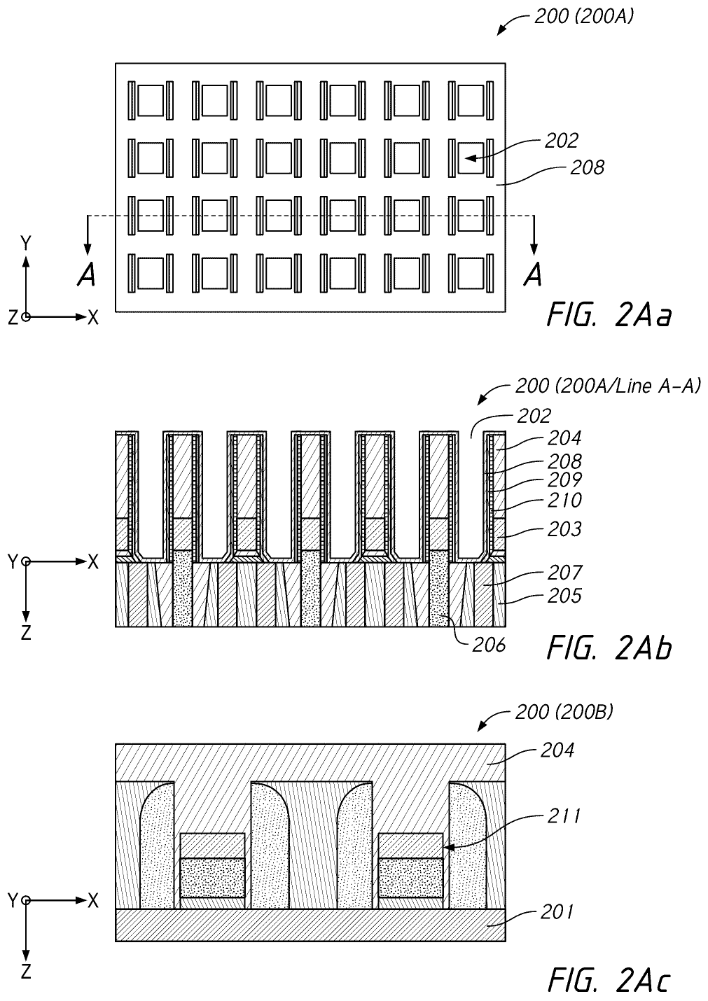

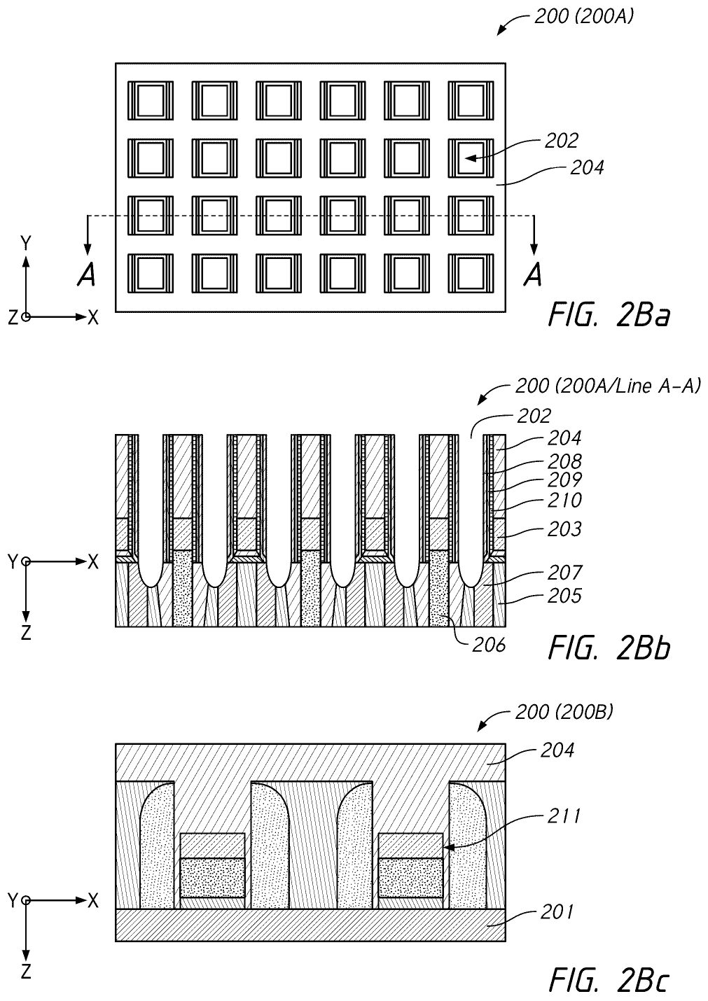

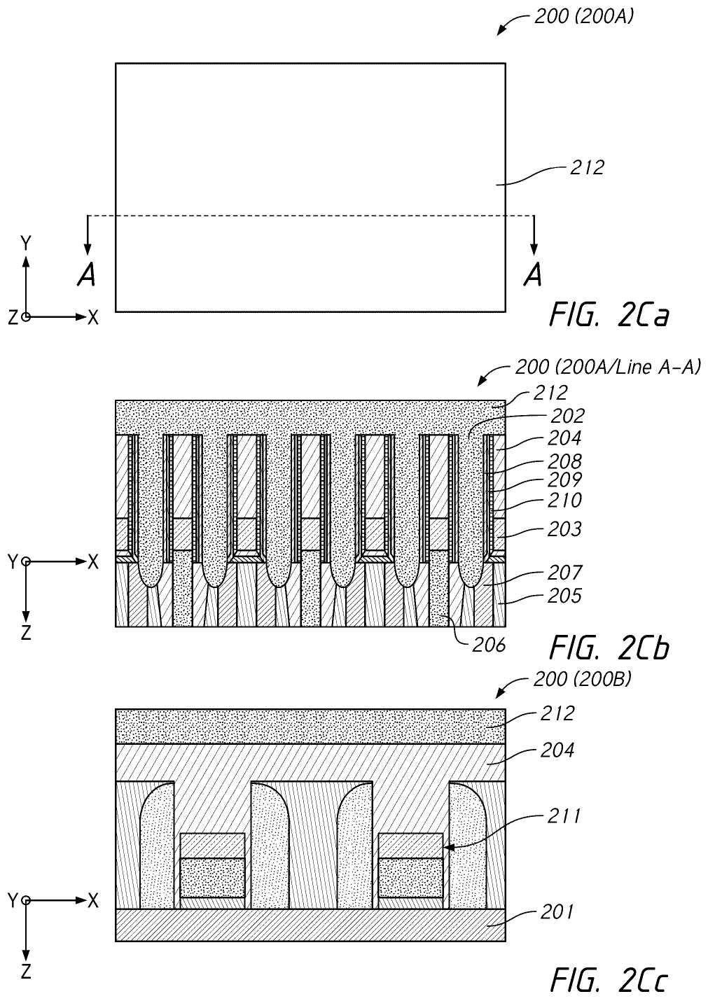

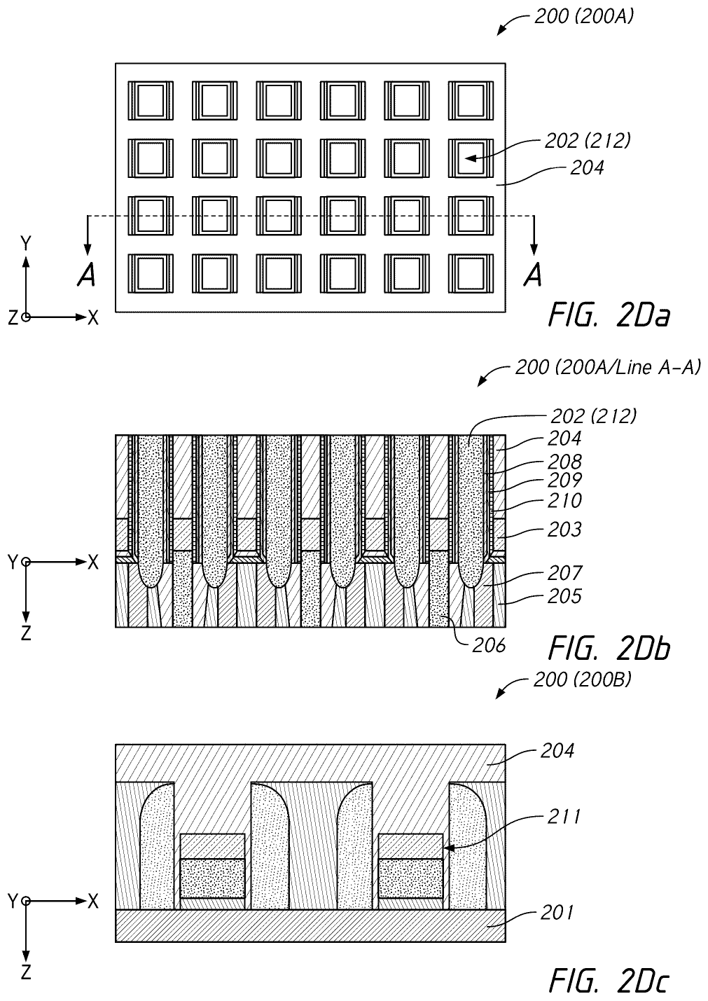

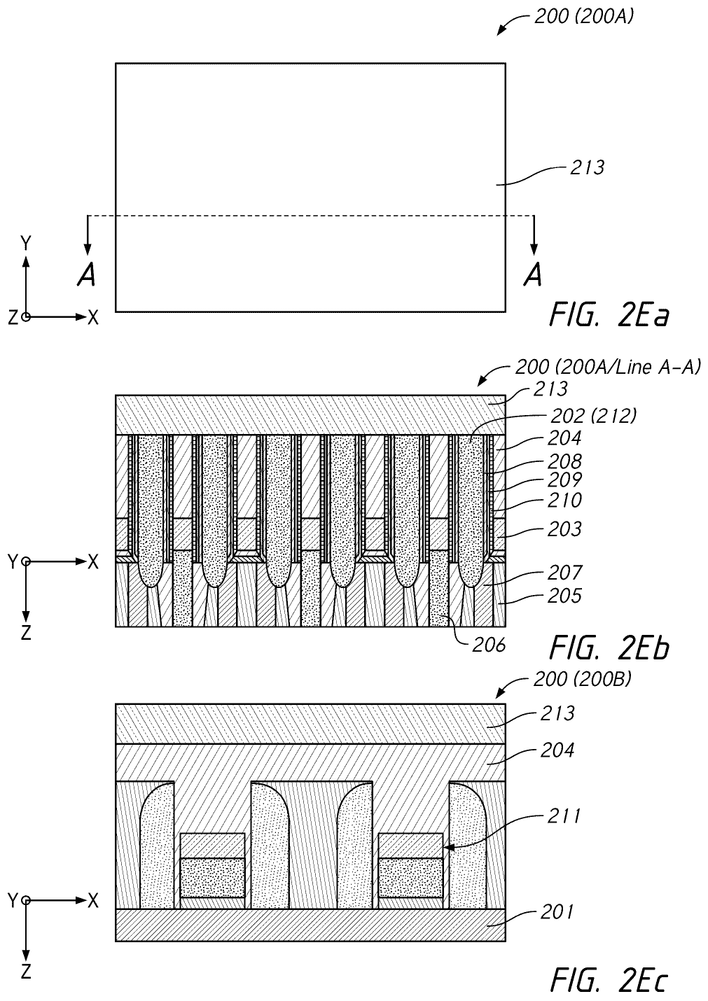

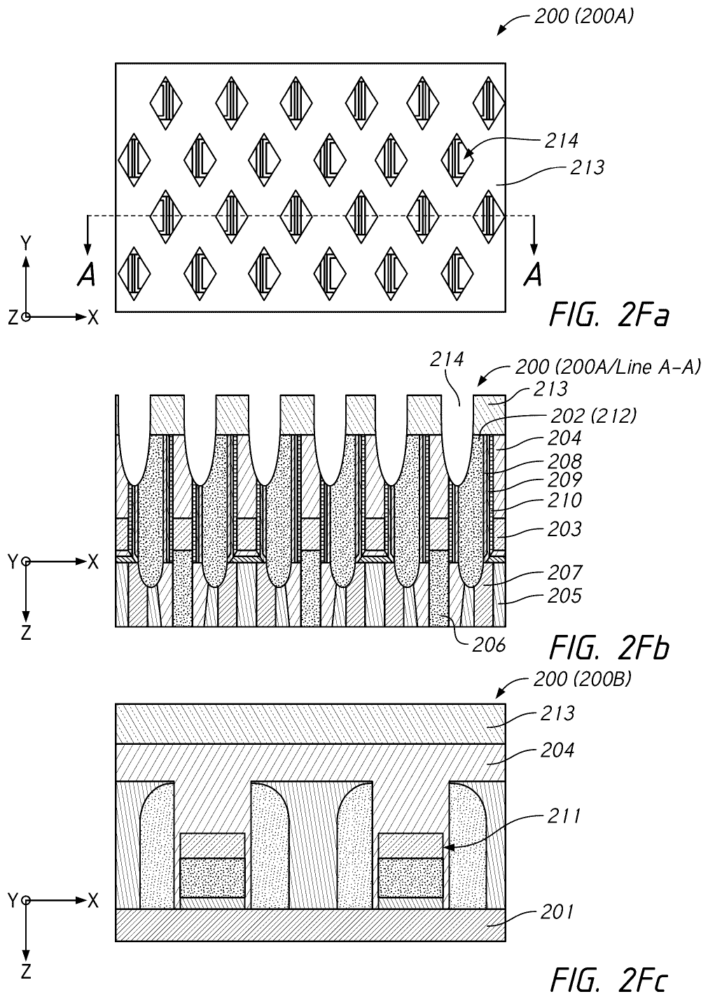

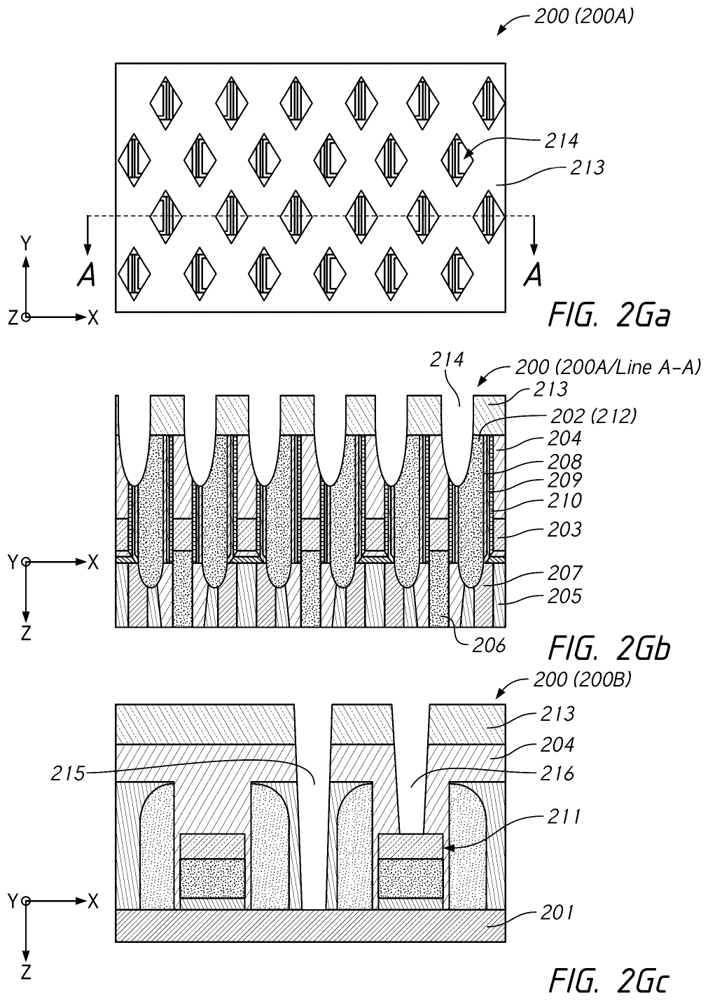

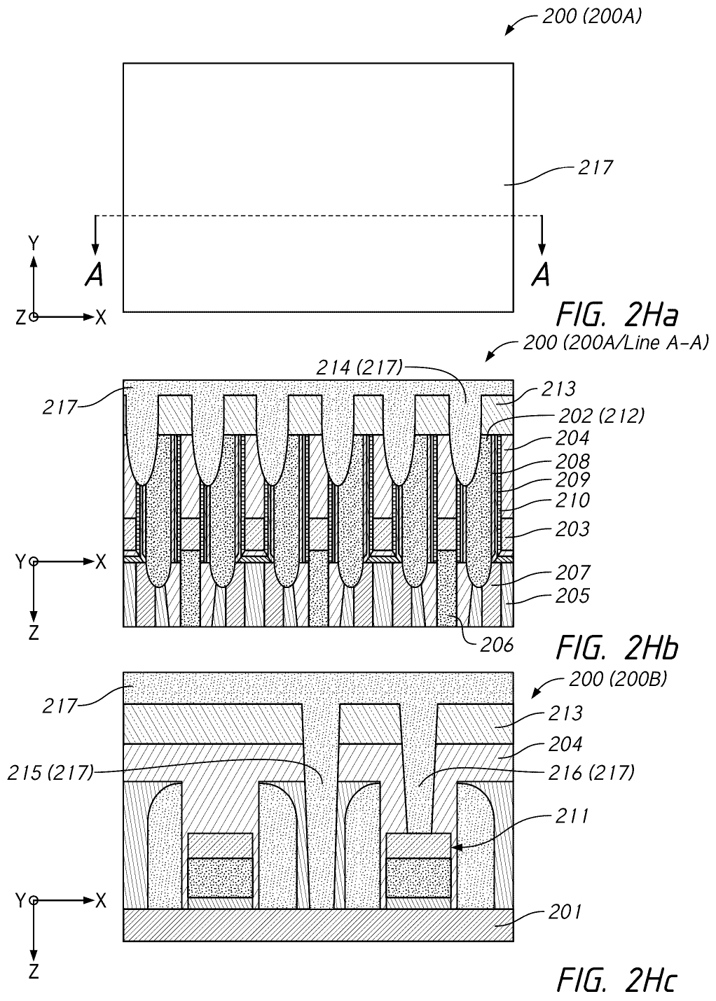

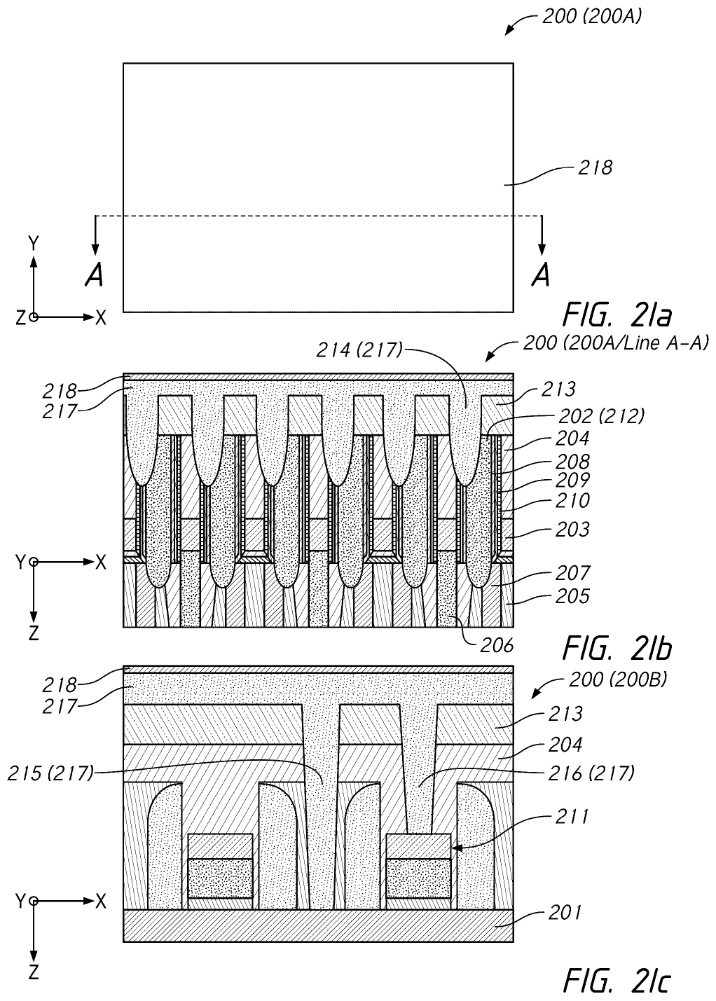

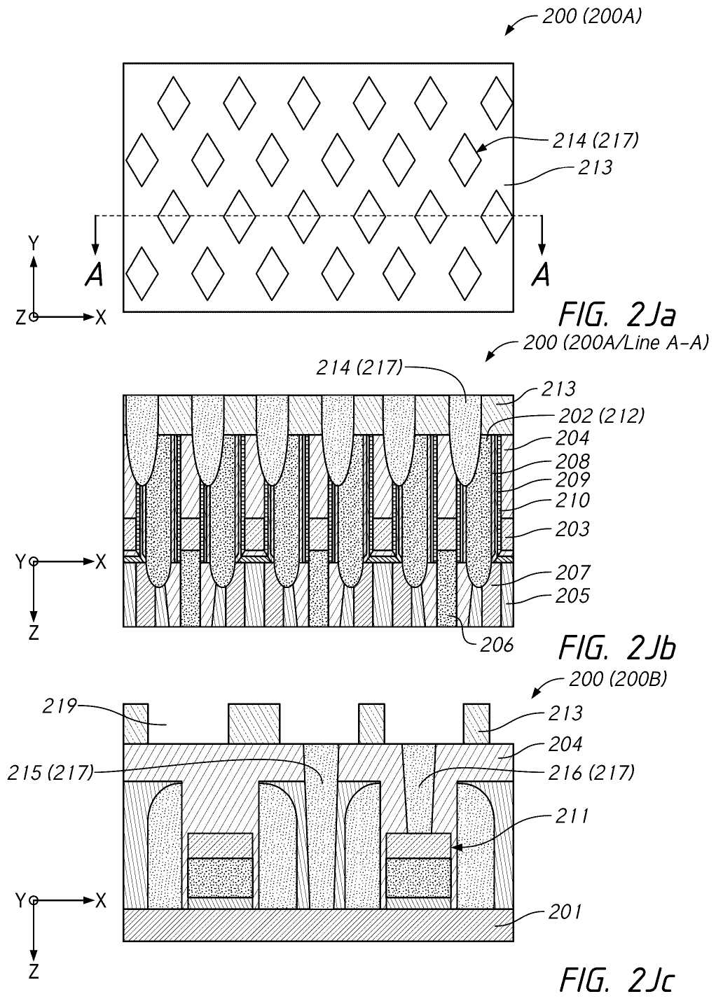

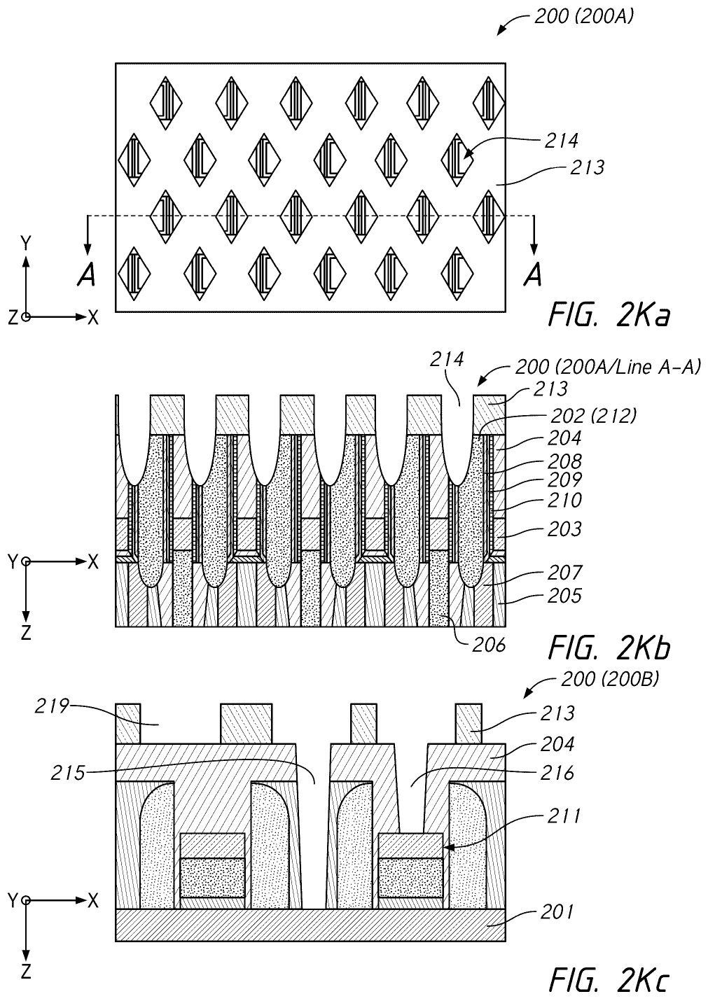

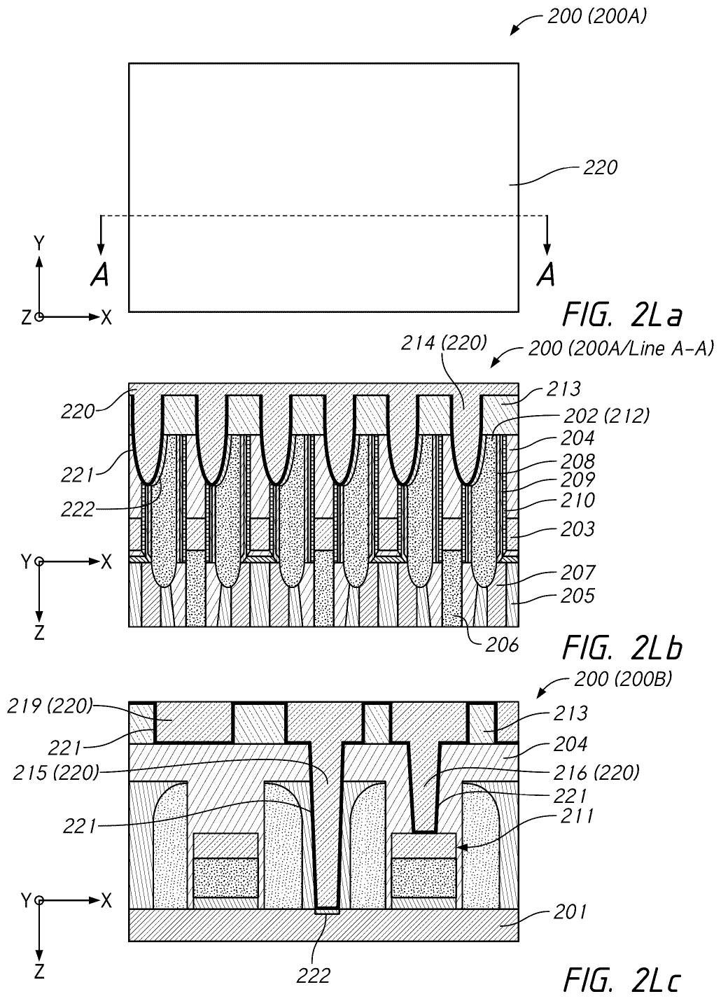

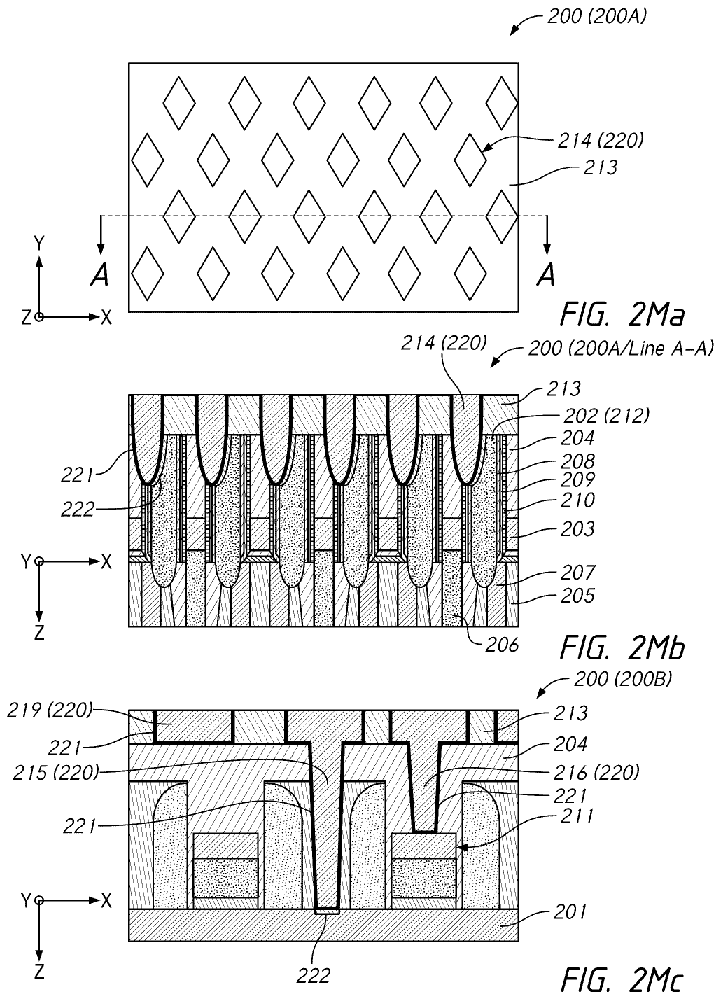

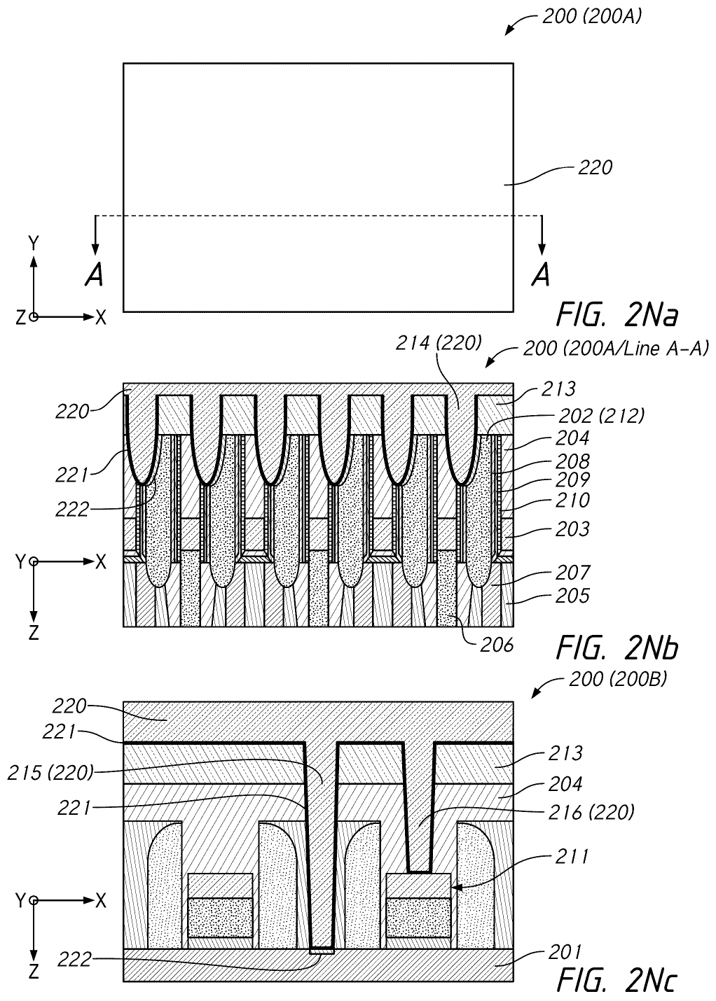

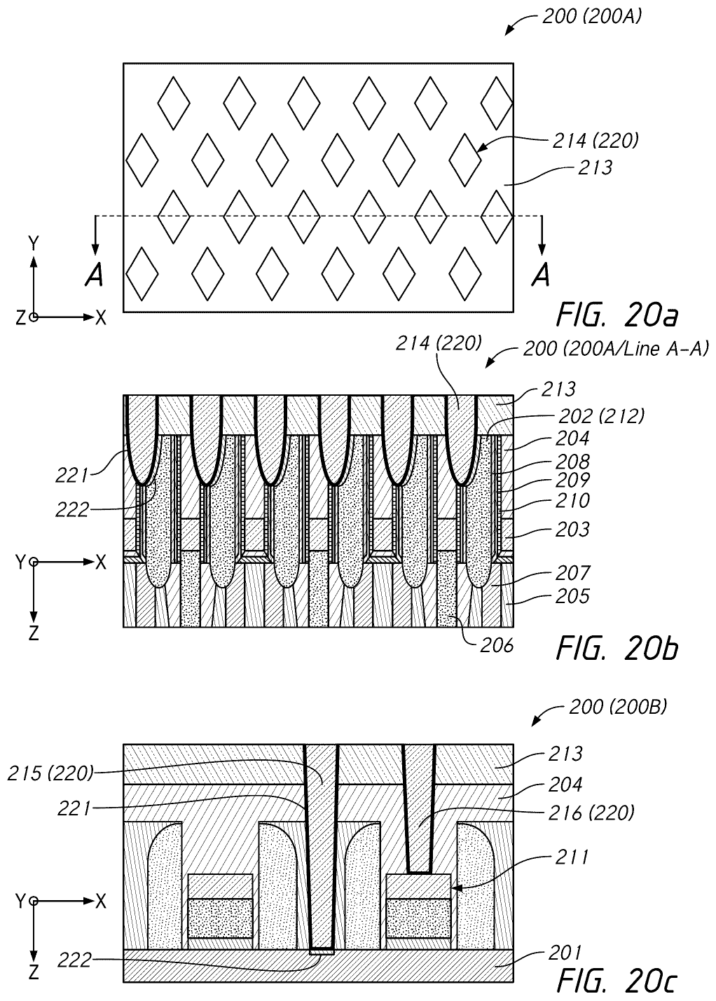

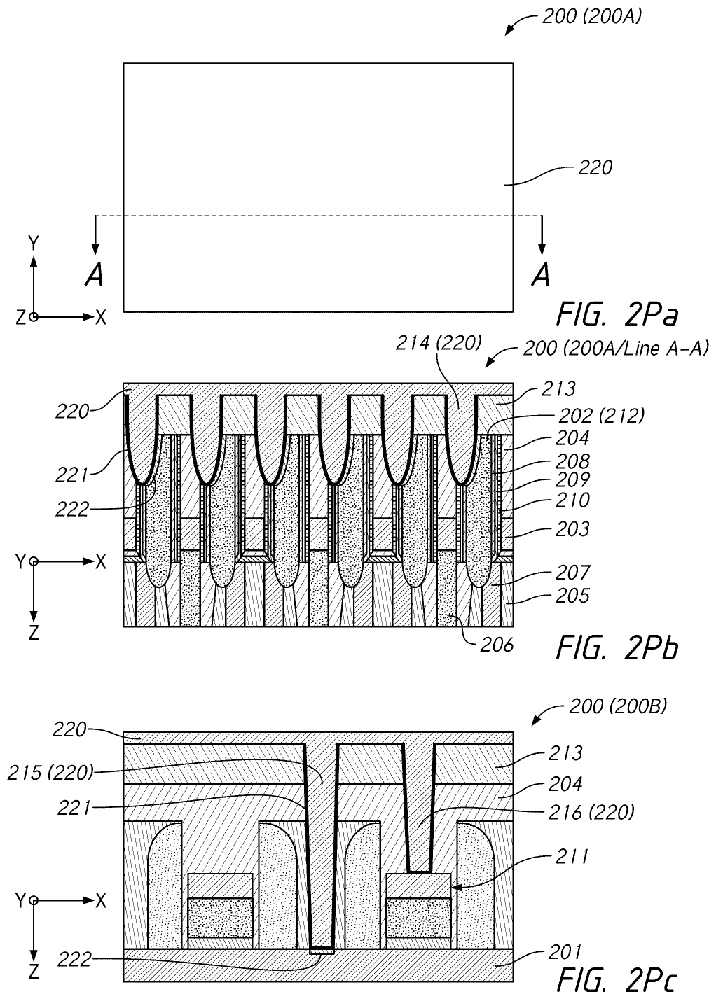

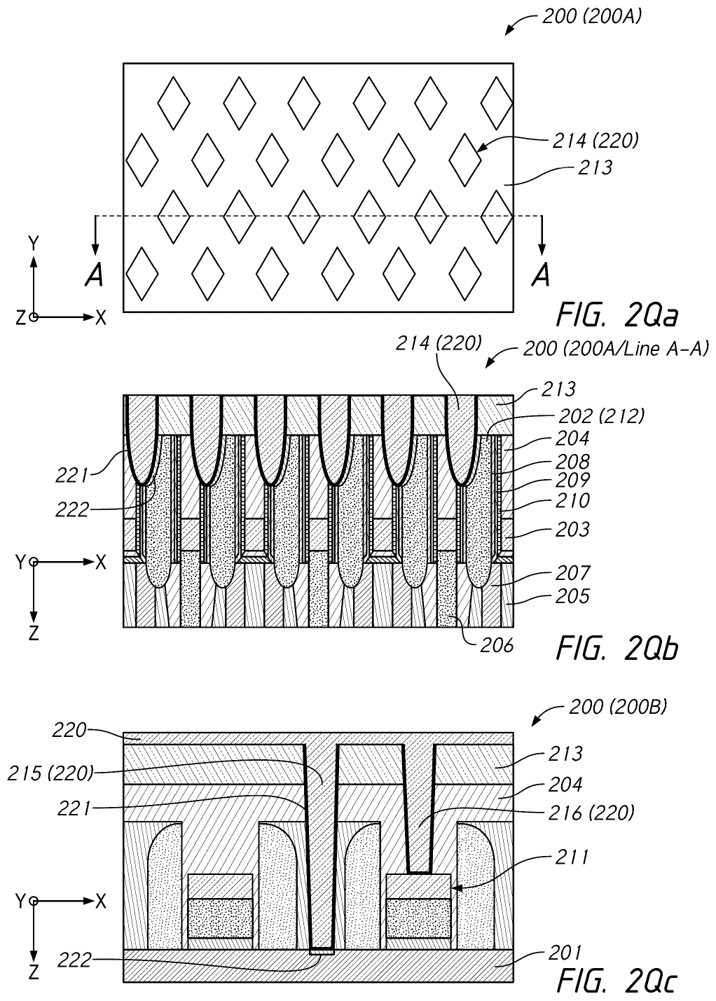

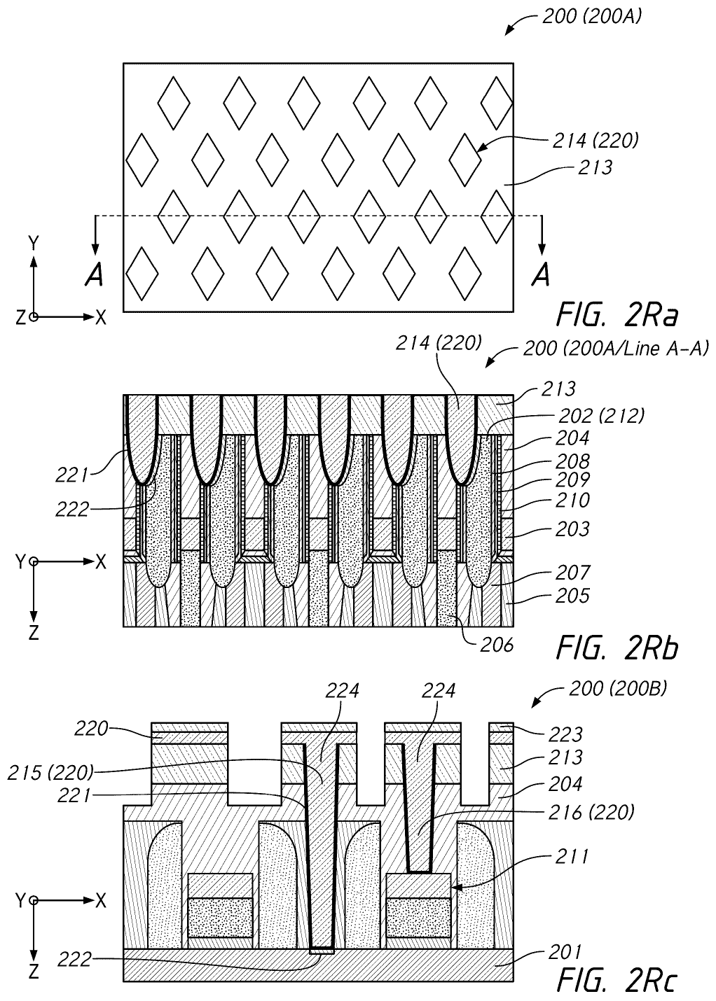

FIGS. 2Aa-2Ac through FIGS. 2Ra-2Rc depict an example of part of processes for forming at least part of a memory device 200 including a memory region 200A and a periphery region 200B according to some embodiments of the disclosure. FIGS. 2Aa-2Ra and FIGS. 2Ab-2Rb each show a plan view and an A-A cross-sectional view of the memory region 200A. FIG. 2Ac-2Rc each show a cross-sectional view of the periphery region 200B. The memory device 200 may be part of the memory device 100 of FIG. 1, and the memory region 200A and the periphery region 200B may be one of the memory regions 110 and one of the periphery regions 111, respectively. The memory region 200A and the periphery region 200B are adjacent to or neighboring each other on a semiconductor substrate 201. The semiconductor substrate may be a semiconductor wafer.

Referring to FIGS. 2Aa-2Ac, a plurality of contact holes 202 are provided to a layer stack structure in the memory region 200A of the memory device 200. The layer stack structure includes a metal layer 203 and a mask layer 204 for the metal layer 203 stacked with one another. The meal layer 203 includes, for example, tungsten (W). The metal layer 203 may form a digit line. The mask layer 204 may include a hard mask. The mask layer 204 may also be referred to as the hard mask 204. The mask layer or the hard mask 204 includes, for example, a nitride. The layer stack structure is on an underlying structure including a shallow trench isolation (STI) structure 205, a digit line contact 206, and an active region 207. The layer stack structure is not limited to the illustrated example. The layer stack structure may include other layers, elements, and structures as appropriate. The underlying structure is not limited to the illustrated example. The underlying structure may include other layers, elements, and structures as appropriate. The contact holes 202 may be formed by conventional methods, such as lithography and etching, as appropriate. The contact holes 202 penetrate from the top layer to the bottom layer of the layer stack structure and reach at least part of a top portion of the underlying structure. A liner 208 is provided to surfaces of the contact holes 202. The liner 208 includes, for example, a nitride. Conventional deposition methods may be used as appropriate. There may also be other layers or films, such as an oxide film 209 and a silicon oxycarbide (SiOC) film 210, on the surfaces of the contact holes 202 as appropriate. In the periphery region 200B of the memory device 200, on the semiconductor substrate 201 is a transistor structure including, for example, a gate structure 211. The transistor structure is not limited to the illustrated example. The transistor structure may include other layers, elements, and structures as appropriate. On the gate structure 211 is the hard mask 204.

Referring to FIGS. 2Ba-2Bc, the contact holes 202 are etched to further the depth in the memory region 200A. A bottom of each of the contact holes 202 penetrates at least part of the underlying structure including the STI structure 205 and the active region 207. The etching also removes some portions of the liner 208, the oxide film 209, and the SiOC film 210 and reveals a top surface (or an upper surface) of the hard mask 204. Conventional dry etching methods may be used as appropriate.

Referring to FIGS. 2Ca-2Cc, a poly layer 212 is provided to fill the contact holes 202 with a poly material in the memory region 200A. The resulting holes are poly-filled (or poly-embedded) contact holes 202 in the memory region 200A. The poly material may be a doped poly silicon. The poly material may include a metal material in addition to poly silicon to be poly-metal. The poly layer 212 is also provided to the top surface of the hard mask 204 in the periphery region 200B.

Referring to FIGS. 2Da-2Dc, the poly layer 212 is etched to reveal at least a top portion of the layer stack structure in the memory region 200A. The poly layer 212 in the periphery region 200B is also etched at the same time. In the example, the etching or etch back (EB), such as dry etching, is stopped at the top surface or at least a top portion of the hard mask 204. The etching conditions, such as bias, temperature, and etching rate, are determined and selected to stop the etching accordingly. Poly contact portions including the poly-filled contact holes 202 (212) are thus formed in the memory region 200A.

Referring to FIGS. 2Ea-2Ec, additional nitride layer 213 is provided on the poly-filled contact holes 202 and the layer stack structure including the hard mask 204 in the memory region 200A as well as the periphery region 200B. Conventional deposition methods may be used as appropriate.

Referring to FIGS. 2Fa-2Fc, a plurality of contact holes 214 for cell contact holes is formed to the respective poly contact portions provided hitherto in the memory region 200A. The contact holes 214 penetrate the additional nitride layer 213, at least part of the poly-filled contact holes 202 (212), and at least part of the layer stack structure. The contact holes 214 are patterned to provide cell contacts. The cell contacts provide part of a redistribution layer (RDL) structure in the memory region 200A. Conventional dray etching methods may be used as appropriate.

Referring to FIGS. 2Ga-2Gc, a plurality of contact holes 215 and 216 for peripheral contact holes are formed in the periphery region 200B. The contact holes 215 may reach an upper surface or an upper portion of the semiconductor substrate 201. The contact holes 215 provide at least part of peripheral contact structures, such as peripheral contacts and peripheral contact plugs. The contact holes 216 may reach an upper surface or an upper portion of the gate structure 211. The contact holes 216 provide at least part of gate peripheral contact structures, such as gate peripheral contacts and gate peripheral contact plugs. The peripheral contact structures and/or the gate peripheral contact structures may provide part of a redistribution layer (RDL) structure in the periphery region 200B. Conventional dray etching methods may be used as appropriate.

According to the present embodiments and examples, as described in connection with FIGS. 2Da-2Dc and 2Ea-2Ec, the etching of the poly layer 212 is stopped at the top surface or at least the top portion of the hard mask 204, and subsequently the additional nitride layer 213 is provided. Accordingly, the height of the hard mask 204 or the total height of the hard mask portion including the hard mask 204 and the additional nitride layer 213 can be further flexibly controlled and adjusted. The etching depth of each of the contact holes 214 in the memory region 200A and the contact holes 215 and 216 in the periphery region 200B, which provide contact structures (such as contacts and contact plugs) in the respective regions as part of the RDL structure, can thus be further flexibly managed. This improves efficiency of a wiring layout and a circuit array layout.

After the process of FIGS. 2Ga-2Gc, there may be two types of a process flow according to some embodiments of the disclosure. One is a dual damascene flow for forming local interconnects and peripheral contacts together. Another is a two-step flow of forming peripheral contacts and subsequently forming local interconnects. Below, the former process flow is first described, and the latter process flow is then described. The local interconnects may provide part of the RDL structure besides the contact holes or the contact structures. The RDL structure may provide part of a local wiring.

As part of the dual damascene flow, referring to FIGS. 2Ha-2Hc, an under layer 217 is coated on top surfaces and/or exposed surfaces of the structure so far formed in the memory region 200A and the periphery region 200B. The under layer 217 fills the contact holes 214 in the memory region 200A and the contact holes 215 and 216 in the periphery region 200B with an under layer material. The under layer material may include a conductive material, such as a metal material.

Referring to FIGS. 2Ia-2Ic, an anti-reflective coating 218, such as a dielectric anti-reflective coating (DARC), is then deposited.

Referring to FIGS. 2Ja-2Jc, the under layer-filled holes 214 and the additional nitride layer 213 are etched in the memory region 200A. Conventional dry etching methods may be used as appropriate. Patterns 219 are also provided in the periphery region 200B. Conventional patterning methods, such as lithography techniques, may be used as appropriate.

Referring to FIGS. 2Ka-2Kc, the residual under layer 217 is removed from the contact holes 214 in the memory region 200A and the contact holes 215 and 216 in the periphery region 200B by, for example, dry strip and cleaning processes.

Referring to FIGS. 2La-2Lc, a conductive layer 220 is provided by, for example, deposition. The conductive layer 220 includes, for example, a metal material, such as tungsten (W). The conductive layer 220 fills the contact holes 214 in the memory region 200A and the contact holes 215 and 216 and the patterns 219 in the periphery region 200B with the conductive material or the metal material. Before the deposition of the conductive layer 220, cobalt (Co) 222 may be provided by sputtering, and titanium (Ti)/titanium nitride (TiN) 221 may be provided by deposition. The cobalt 222 and the Ti/TiN 221 cover the surfaces of the contact holes 214 in the memory region 200A and the contact holes 215 and 216 and the patterns 219 in the periphery region 200B. The Ti/TiN 221 may provide a barrier layer. The conductive layer 220 is deposited onto the Ti/TiN barrier layer 221. The conducive material-filled contact holes 214 provide at least part of cell contact structures, such as cell contacts and cell contact plugs, in the memory region 200A. The cell contacts may provide part of the redistribution layer structure in the memory region 200A. The conductive material-filled contact holes 215 and 216 provide at least part of peripheral contact structures, such as peripheral contacts and peripheral contact plugs, and at least part of gate peripheral contact structures, such as gate peripheral contacts and gate peripheral contact plugs, respectively, in the periphery region 200B. The peripheral contact structures and/or the gate peripheral contact structures may provide part of the redistribution layer structure in the periphery region 200B. The conductive material-filled patterns 219 provide another part of the redistribution layer structure in the periphery region 200B. The conductive material-filled patterns 219 provide local interconnects, such as contact pads, electrically connected or coupled to the contact structures in the periphery region 200B.

Referring to FIGS. 2Ma-2Mc, a chemical mechanical polishing (CMP) is performed to remove part of the conductive layer 220 and to separate, from one another, the contact holes 214, the contact holes 215 and 216, and the patterns 219.

As for the two-step flow following the process of FIGS. 2Ga-2Gc, the first step thereof provides the contact structures in the periphery region 200B. Referring to FIGS. Na-Nc, the conductive layer 220 is deposited in the memory region 200A and the periphery region 200B. The conductive layer 220 fills the contact holes 214 in the memory region 200A and the contact holes 215 and 216 in the periphery region 200B with the conductive material. The sputtering of the cobalt (Co) 220 and the deposition of the Ti/TiN 221 are also performed prior to the deposition of the conductive layer 220. Referring to FIGS. 2Oa-2Oc, a chemical mechanical polishing (CMP) is performed to remove the conductive layer 220 as well as the Ti/TiN layer 221 on the additional nitride layer 213 and to separate, from one another, the contact holes 214 and the contact holes 215 and 216.

Following the first step, the second step of the two-step flow provides local interconnects or local interconnect structures. Referring to FIGS. 2Pa-2Pc, the conductive layer 220 is again deposited on the top portions of the structures formed so far in the memory region 200A and the periphery region 200B. Referring to FIGS. 2Qa-2Qc, part of the conductive layer 220 is removed to reveal top portions of the conductive material-filled contact holes 214 in the memory region 200A. Conventional dry etching methods and/or lithography methods with a patterning reticle may be used as appropriate. During this process, the conductive layer 220 remains on the top portion of the structure in the periphery region 200B. Referring to FIGS. 2Ra-2Rc, patterning is performed to the periphery region 200B using a mask layer 223 to shape the underlying layers including the hard mask 204, the additional nitride layer 213, and the conductive layer 220 in the periphery region 200B and form local interconnects (or local interconnect structures) 224 at appropriate positions. The local interconnects 224 may provide contact pads to the conductive material-filled contact holes 215 and 216 that provide the contact structures in the periphery region 200B. Conventional etching and/or lithography methods may be used as appropriate.

According to the present embodiments and examples, the dual damascene flow can improve a re-sputtering mode of the conductive layer 220. According to the present embodiments and examples, the two-step flow can enlarge the distance between the gate structure 211 and the local interconnects 224. The parasitic capacity can thus be effectively reduced.

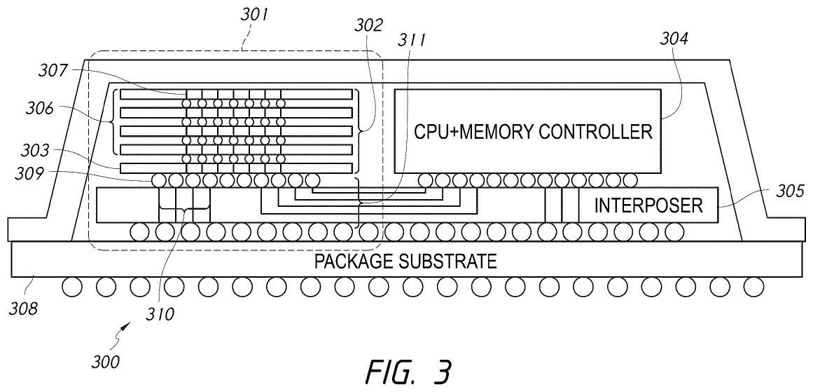

FIG. 3 depicts an example of a schematic configuration of a semiconductor system 300 according to an embodiment of the disclosure. The semiconductor system 300 includes a semiconductor apparatus, which is a memory device 301 in an embodiment of the disclosure. The memory device 301 may be the memory device 100 and/or the memory device 200. The semiconductor system 300 may also include a central processing unit (CPU) and memory controller 304, which may be a controller chip, on an interposer 305 on a package substrate 308. The interposer 305 may include one or more power lines 310 which may supply power supply voltage from the package substrate 308. The interposer 305 may include a plurality of channels 311 that may interconnect the CPU and memory controller 304 and the memory device 301. For example, the memory device 301 may be a dynamic random access memory (DRAM). The memory controller 304 may provide a clock signal, a command signal, and may further transmit and receive data signals. The plurality of channels 311 may transmit the data signals between the memory controller and the memory device 301. The memory device 301 may include a plurality of dies (or chips) 302 including at least one interface (IF) die (or chip) 303 and a plurality of memory core dies (or chips) 306 stacked with each other. A number of the memory core dies 306 may not be limited to 4 and may be more or fewer as appropriate. Each of the memory core dies 306 may include a plurality of memory cells and circuitries accessing the memory cells. For example, the memory cells may be DRAM cells. The memory cells may be arranged in array. The memory device 301 may include conductive vias 307 which couple the IF die 303 and the memory core dies 306 by penetrating the IF die 303 and the memory core dies 306. The conductive vias 307 may be TSVs. The IF die 303 may be coupled to the interposer 305 via interconnects 309. For example, the interconnects 309 may be microbumps having bump pitches of less than about or less than one hundred micrometers and exposed on an outside of the IF die 303. A portion of each of the interconnects 309 may be coupled to the one or more power lines 310. Another portion of each of the interconnects 309 may be coupled to one or more of the channels 311.

DRAM is merely one example of the memory device 301, and the embodiments and the above descriptions thereof are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the memory device 801. Furthermore, devices other than memory, including logic ICs, such as a microprocessor and an application-specific integrated circuit (ASIC), are also applicable as the semiconductor device according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. A method, comprising:
forming a plurality of poly contact portions on a semiconductor substrate;
forming a plurality of contact holes to the plurality of poly contact portions; and
forming a plurality of conductive portions to the plurality of contact holes.

2. The method according to claim 1, wherein each of the poly contact portions includes one or more poly-filled contact holes.

3. The method according to claim 1, wherein
forming the plurality of poly contact portions includes:
forming a plurality of first contact holes to a layer stack structure on the semiconductor substrate, the layer stack structure including a metal layer and a mask layer over the metal layer;
providing a poly layer to fill the first contact holes with a poly material; and
etching the poly layer until a top surface of the mask layer, and
the contact holes formed to the poly contact portions are second contact holes.

4. The method according to claim 3, wherein the mask layer includes a nitride.

5. The method according to claim 1, forming the plurality of poly contact portions includes forming the plurality of poly contact portions in a memory region on the semiconductor substrate.

6. The method according to claim 1, wherein forming the plurality of contact holes includes:
providing additional nitride layer at least on the poly contact portions; and
patterning the additional nitride layer and the poly contact portions to form the contact holes.

7. The method according to claim 1, wherein forming the plurality of conductive portions includes providing a conductive layer to fill the contact holes with a conductive material.

8. The method according to claim 7, wherein at least part of the conductive layer provides part of a redistribution layer structure, and at least part of the conductive material-filled contact holes provides contacts as another part of the redistribution layer structure.

9. The method according to claim 7, wherein providing the conductive layer includes providing the conductive layer in a memory region and/or a periphery region.

10. The method according to claim 7, further comprising applying chemical mechanical polishing to at least part of the conducive layer.

11. The method according to claim 1, further comprising a dual damascene process to form local interconnects and contacts.

12. The method according to claim 11, the local interconnects and the contacts are formed in a memory region and/or a periphery region.

13. The method according to claim 11, the local interconnects and the contacts provide part of a redistribution layer structure.

14. The method according to claim 1, further comprising forming contacts and subsequently forming local interconnects.

15. The method according to claim 14, the contacts and the local interconnects are formed in a memory region and/or a periphery region.

16. The method according to claim 14, the contacts and the local interconnects provide part of a redistribution layer structure.

17. A method, comprising:
forming a plurality of poly contact portions on a semiconductor substrate, each of the poly contact portions including one or more poly filled contact holes, wherein forming the plurality of poly contact portions includes:
forming a plurality of first contact holes to a layer stack structure on the semiconductor substrate, the layer stack structure including a metal layer and a mask layer over the metal layer, the mask layer including a nitride;
providing a poly layer to fill the first contact holes with a poly material; and
etching the poly layer until a top surface of the mask layer; and
forming a plurality of second contact holes to the plurality of poly contact portions; and
forming a plurality of conductive portions to the plurality of second contact holes.

18. The method according to claim 17, wherein forming the plurality of second contact holes further includes:
providing additional nitride layer at least on the poly contact portions; and
patterning the additional nitride layer and the poly contact portions to form the second contact holes.

19. A method, comprising:
forming a plurality of poly contact portions on a semiconductor substrate, each of the poly contact portions including one or more poly filled contact holes, wherein forming the plurality of poly contact portions includes:
forming a plurality of first contact holes to a layer stack structure on the semiconductor substrate, the layer stack structure including a metal layer and a mask layer over the metal layer, the mask layer including a nitride;
providing a poly layer to fill the first contact holes with a poly material; and
etching the poly layer until a top surface of the mask layer;
forming a plurality of second contact holes to the plurality of poly contact portions, wherein forming the plurality of second contact holes includes:
providing additional nitride layer at least on the poly contact portions; and
patterning the additional nitride layer and the poly contact portions to form the second contact holes;
forming a plurality of conductive portions to the plurality of second contact holes; and
performing a dual damascene process to form local interconnects and contacts in a memory region and/or a periphery region of a memory device.

20. The method according to claim 19, the local interconnects and the contacts provide part of a redistribution layer structure.
